(19) United States
(12) Patent Application Publication
(10) Pub. No.: US 2025/0189890 A1
(43) Pub. Date: Jun. 12, 2025

(54) UV-stabilized Photo Nanoimprint Lithography Resin

(71) Applicant: Addison Clear Wave Coatings, Inc., St. Charles, IL (US)

(72) Inventors: Chau Ha, Glen Ellyn, IL (US); Martin Newcomb, Glen Ellyn, IL (US)

(73) Assignee: Addison Clear Wave Coatings, Inc., St. Charles, IL (US)

(21) Appl. No.: 18/970,313

(22) Filed: Dec. 5, 2024

Related U.S. Application Data
(60) Provisional application No. 63/608,629, filed on Dec. 11, 2023.

(51) Int. Cl. G03F 7/038; G03F 7/20

(52) U.S. Cl. CPC G03F 7/038; G03F 7/2014

(57) ABSTRACT

A UV-stabilized photo nanoimprint lithography (P-NIL) resin is disclosed. The P-NIL resin comprises: an organic binder selected from the group consisting of: acrylate monomeric components, acrylate oligomeric polymerizable components, and acrylated polymers; titanium oxide (TiO₂) inorganic nanoparticles dispersed in the P-NIL resin, the titanium oxide inorganic nanoparticles having one or more metal oxides coated on or added into the titanium oxide particles, the metal oxides are selected from the group consisting of: SiO₂, Al₂O₃, ZrO₂, SnO₂, and NiO; and a light-activated initiator for polymerization of acrylates. The P-NIL resin may optionally include a radical scavenger selected from the group consisting of the HALS type, ascorbate type, and hydroquinone type; and optionally includes an adhesion promoter for acrylates.

### CROSS-REFERENCE TO RELATED APPLICATION

This application is a non-provisional patent application claiming priority under 35 USC § 119 (e) to U.S. Provisional Patent Application Ser. No. 63/608,629 filed on Dec. 11, 2023.

### FIELD OF THE INVENTION

The present disclosure generally relates to nanoimprint lithography, and more specifically relates to resins used in nanoimprint lithography.

### BACKGROUND

Imprint lithography is an economical method for embossing features on hard substrates used for mass production of optical, optoelectronic, or electronic components containing nanometer-sized features. When the features are on the micrometer or nanometer scales, the terms micro-imprint lithography and nanoimprint lithography are used. For UV photolysis curing, the term photo nanoimprint lithography, or P-NIL or UV-NIL, replacing the older term 2P (for photo-polymer).

In one version of NIL, a curable resin, the imprint resin, is applied to a pattern or mold and cured by either heat or photolysis that initiates polymerization of the resin. The imprinted material is then removed from the mold, and the mold can be reused. In general, NIL methodologies offer a promise of low cost, short cycle time, and high yield manufacturing processes for sub-micrometer components of small devices. Photo nanoimprint lithography (P-NIL) or UV nanoimprint lithography (UV-NIL) is a cost-effective process used for mass production of optical, optoelectronic, or electronic components containing nanometer-sized features.

In a general P-NIL process, a fluid resin may be coated or applied on a substrate such as glass or silicon. The resin may contain a solvent. If so, solvent removal is necessary and may be achieved by heating the resin on the substrate. A stamp or master template containing nanometer-sized features is pressed onto the resin. The resin is then cured via photolysis using ultraviolet (UV), heat, or visible light. Afterwards, the stamp is removed to produce an embossed product. A high tensile strength and stiffness are important mechanical properties for a P-NIL or 2P resin. The absence of shrinkage during both a curing process and in a cured state is an important property for a P-NIL resin.

P-NIL methods can be used for production of photonic and optical applications such as diffractive optical elements (DOE) including optical diffusers and waveguides that control the phase of transmitted light. For these applications, the refractive index (RI) of the resist is an important consideration. In optics, the refractive index of a material describes how fast light travels through the material.

High refractive index (high RI) materials are employed in optical applications for personal devices including augmented, virtual, or mixed realities (AR, VR, MR), lenses, waveguides and the like. The high RI provides a wide field of view, and high refractive index glass is available. Features can be embossed on the high RI glass by NIL technology methods using resins that match the high refractive index of the glass or substrate to prevent reflections. UV cure P-NIL is a commonly used method due to the economic advantage of fast UV-cure processes.

High refractive index NIL resins typically are hybrid resins with a polymerizable organic component and a high refractive index inorganic filler. The inorganic filler is comprised of nanoparticles of high refractive index metal oxide capped with an organic layer that prevents agglomeration. A metal oxide often used is titanium oxide (TiO₂) which does not absorb light in the visible region and has an inherently high refractive index in the range of 2.7 to 2.9 at 589 nm depending on the crystal structure.

A shortcoming of TiO₂ in P-NIL resins is that it behaves as a photo-catalyst with UV light, absorbing the UV light and, in the presence of oxygen, producing reactive oxygen species (ROS) that degrade organic components in the medium. Degradation of the polymerized film and the organic capping materials results in the development of yellow coloration of the film, loss of integrity of the polymeric network, and reduction of the refractive index, presumably due to nanoparticle agglomeration. UV degradation can be quite rapid with some TiO₂-containing P-NIL resins effectively destroyed within hours under the relatively modest UV stress conditions used in a standard ASTM method for evaluating UV-stability of plastics in sunlight.

Hence, it is desirable to have UV-stable high refractive index P-NIL resins for use in optical devices that may be exposed to sunlight without degradation.

### SUMMARY OF THE DISCLOSURE

In one embodiment, a UV-stabilized photo nanoimprint lithography (P-NIL) resin is disclosed. The P-NIL resin comprises: an organic binder selected from the group consisting of: acrylate monomeric components and acrylate oligomeric polymerizable components; titanium oxide inorganic nanoparticles dispersed in the P-NIL resin, the titanium oxide inorganic nanoparticles having one or more metal oxides coated on or added into the titanium oxide particles, the metal oxides are selected from the group consisting of: SiO₂, Al₂O₃, ZrO₂, SnO₂, and NiO; and a light-activated initiator for polymerization of acrylates. The P-NIL resin may optionally include a radical scavenger selected from the group consisting of the HALS type, ascorbate type, and hydroquinone type; and optionally includes an adhesion promoter for acrylates.

In another embodiment, a photo nanoimprint lithography (P-NIL) resin is disclosed. The resin comprises a polymerizable organic component, nanoparticles having titanium oxide or titanium oxide, and a photoinitiator for curing the polymerizable organic component. The nanoparticles are modified with one or more additional metal oxides selected from the group consisting of SiO₂, Al₂O₃, ZrO₂, SnO₂, and NiO.

A method for fabricating high-resolution nanometer features using a UV-stabilized photo nanoimprint lithography (P-NIL) resin is disclosed. The method comprises: providing a P-NIL resin having: a polymerizable organic component, a titanium oxide nanoparticle modified with one or more additional metal oxides selected from the group consisting of SiO₂, Al₂O₃, ZrO₂, SnO₂, and NiO, and a photoinitiator; applying the resin onto a substrate; pressing a mold containing nanometer-sized features into the resin; curing the resin using ultraviolet (UV) light; and removing the mold to produce a cured resin with nanometer features.

### BRIEF DESCRIPTION OF THE DRAWINGS

FIG. 1 is a flow chart of the steps in a photo nanoimprint lithography process using the 2P resin of the present disclosure, according to an embodiment of the disclosure.

### DETAILED DESCRIPTION OF THE DISCLOSURE

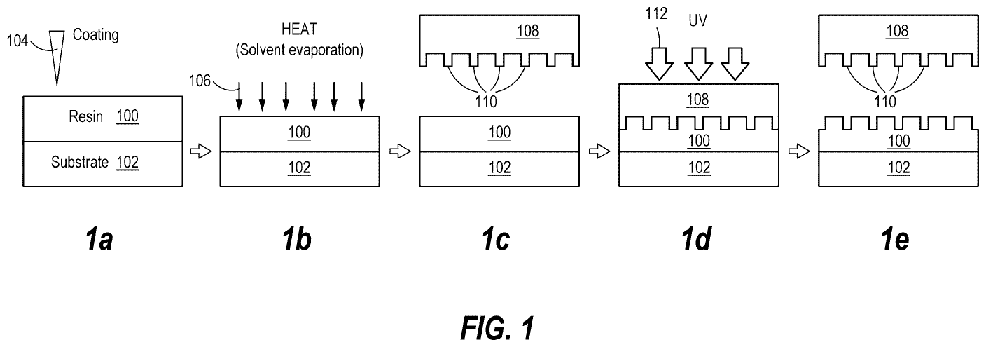

Referring now to the drawings, and with specific reference to the depicted P-NIL process illustrated in FIG. 1, a photo nanoimprint lithography (P-NIL) resin 100 having a high refractive index and high mechanical performance used in photo nanoimprint lithography (P-NIL) or UV nanoimprint lithography and the method of formulating the P-NIL resin 100 for P-NIL applications is disclosed herein. The P-NIL resin 100 may be a high refractive index organic/inorganic resins used for P-NIL applications. The P-NIL resin 100 may have substantially higher RI than conventional organic resins and exhibits acceptable mechanical or toughness performance properties. The P-NIL resin 100 may be formulated for use in photonic and optical applications such as optical diffusers and waveguides, and in AR/VR/MR devices.

As shown in FIG. 1, a P-NIL process is illustrated using the P-NIL resin 100 disclosed herein. When conducting a P-NIL process, the P-NIL resin 100 is dispensed or “coated” on a substrate 102 via a coating device 104, as shown in FIG. 1a. The P-NIL resin 100 may contain an optional solvent. If the P-NIL resin 100 contains a solvent, the solvent may be removed by applying heat 106 to the P-NIL resin 100 for evaporating the solvent after coating on the substrate 102, as shown in FIG. 1b, and as generally known in the arts. A stamp 108, also referred to as a pattern, is then pressed into the P-NIL resin 100 as shown in FIGS. 1c-1d. The stamp 108 may include nanometer features 110 which get embossed on the P-NIL resin 100. As shown in FIG. 1d, the P-NIL resin 100 may be cured via photolysis 112 by using UV or visible light. Lastly, the stamp 108 is removed, as shown in FIG. 1e, resulting in the cured P-NIL resin 100 having the nanometer features 110 imprinted on the P-NIL resin 100.

In one embodiment, the P-NIL resin 100 comprises an organic compound or organic binder and inorganic nanoparticles mixed together in a pre-polymerized liquid medium. The P-NIL resin 100 comprising both an organic compound and inorganic nanoparticles can be used at room temperature in the P-NIL technique to maintain a high RI value and maintain excellent mechanical properties, such as a glass transition temperature. The increased RI of the P-NIL resin 100 will allow device miniaturization in photonic and optical application such as in optical diffusers, waveguides, and optical elements for AR/VR/MR applications

The organic compound may be chosen from the group consisting of acrylate-based monomers and oligomers and acrylated polymers with an RI value greater than 1.4 at 589 nm.

The inorganic nanoparticles of the P-NIL resin 100 are nanometer-sized particles of titanium oxide (titania, TiO₂) that are modified such that the photocatalytic oxidation effect is suppressed. In order to avoid light scattering and maintain clarity of the formulations, these particles should be less than 50 nm, or less than 30 nm, and also have a high RI value greater than 1.6 at 589 nm.

The photocatalytic oxidation effect that occurs with conventional TiO₂ is suppressed by adding another metal oxide or mixture of metal oxides onto or into the titanium oxide, TiO₂. Metal oxides that may be used include: silicon dioxide (SiO₂), aluminum oxide (Al₂O₃), stannic oxide (SnO₂), nickel oxide (NiO) and zirconium oxide (ZrO₂). These metal oxides prevent oxygen from reaching the photo-activated TiO₂ particles and/or deactivate the photo-activated TiO₂ and thus inhibit production of reactive oxygen species. The modified TiO₂ particles are subsequently capped with organic capping agent or agents to promote dispersion and inhibit agglomeration, as is generally known in the art.

In addition, the P-NIL resin 100 may contain anti-oxidant materials that scavenge reactive oxygen species. The anti-oxidants that may be incorporated in the P-NIL resin 100 include hindered amine light stabilizers (HALS) such as commercial Tinuvin® products, hydroquinone type compounds, and ascorbates and related hydroxy compounds. The purpose of these agents is to scavenge small amounts of reactive oxygen species to extend further the lifetimes of the cured high refractive index films.

Monomers, oligomers and additives may be further provided in the P-NIL resin 100 to maintain appropriate viscosities for imprinting the P-NIL resin 100 with masters or working stamps used in P-NIL applications. The acrylate monomers and oligomers used in these resins were selected to maintain appropriate levels of fluidity for P-NIL applications such that the P-NIL resin 100 can flow into a working stamp by capillary action. The UV catalysts used in the P-NIL resin 100 may be commercially available UV catalysts designed to initiate radical reactions when irradiated with UV-A light from a mercury lamp or 320 nm to 405 nm UV light from an LED.

### Examples

In one embodiment of the formulation, an acrylate base resin containing a mixture of acrylate monomers and oligomers, a Tinovin® HALS anti-oxidant, a radical initiator, and an adhesion promoter was mixed with titanium oxide nanoparticles containing tin oxide and zirconium oxide in an amount that resulted in a refractive index of 1.71 at 589 nm for the cured film. (Formulation A)

In another embodiment of the formulation, an acrylate base resin containing a mixture of acrylate monomers and oligomers, a Tinovin® HALS anti-oxidant, a radical initiator, and an adhesion promoter was mixed with titanium oxide nanoparticles containing aluminum oxide and zirconium oxide in an amount that resulted in a refractive index of 1.76 at 589 nm for the cured film. (Formulation B)

In another embodiment of the formulation, an acrylate base resin containing a mixture of acrylate monomers and oligomers, a Tinovin® HALS anti-oxidant, a radical initiator, and an adhesion promoter was mixed with titanium oxide nanoparticles containing tin oxide and zirconium oxide in an amount that resulted in a refractive index of 1.79 at 589 nm for the cured film. (Formulation C)

In another embodiment of the formulation, an acrylate base resin containing a mixture of acrylate monomers and oligomers, a Tinovin® HALS anti-oxidant, a radical initiator, and an adhesion promoter was mixed with titanium oxide nanoparticles containing tin oxide and aluminum oxide in an amount that resulted in a refractive index of 1.83 at 589 nm for the cured film. (Formulation D)

In another embodiment of the formulation, an acrylate base resin containing a mixture of acrylate monomers and oligomers, a Tinovin® HALS anti-oxidant, a radical initiator, and an adhesion promoter was mixed with titanium oxide nanoparticles containing tin oxide and zirconium oxide in an amount that resulted in a refractive index of 1.85 at 589 nm for the cured film. (Formulation E)

In another embodiment of the formulation, an acrylate base resin containing a mixture of acrylate monomers and oligomers, a Tinovin® HALS anti-oxidant, a radical initiator, and an adhesion promoter was mixed with titanium oxide nanoparticles containing tin oxide and zirconium oxide in an amount that resulted in a refractive index of 1.93 at 589 nm for the cured film. (Formulation F)

Formulations prepared with TiO₂ nanoparticles with no additional metal oxides were prepared for comparisons (Formulations X1 and X2). With the exception that there was no additional metal oxide, these formulations were similar to formulations A-F in terms of the acrylate base resins and initiators.

### Results:

UV-stability of the formulations was evaluated by measuring the refractive indices of 0.8-2.0 micron thick cured films coated on glass. The films were exposed to UV-light in a Q-Sun® xenon arc test chamber (Q-Lab Corporation) using a Daylight Q filter that produces an irradiance spectrum matching outdoor sunlight. The conditions employed were 0.35 W/(m²·nm) at 340 nm and 45° C. The criterion used for evaluating UV-induced destruction of the high RI film was a reduction in the RI at 589 nm by 0.05 RI units. For example, if the high RI film initially had an RI of 1.75 at 589 nm, then reduction of the RI of the film to 1.70 or below would be classified as destruction. From a practical perspective, this level of reduction in the RI would be equivalent to a film that likely would be judged as unacceptable in original construction of the device. The Table gives results of the UV-stability studies.

A film from formulation X1 containing titanium oxide nanoparticles at low concentration was destroyed within two days of irradiation. A film from formulation X2 containing higher titanium oxide nanoparticle concentration was destroyed within one day. Films from formulations containing titanium oxide nanoparticles with added metal oxides were appreciably more stable when irradiated than those without added metal oxides and a HALS agent. Those with a low titanium oxide content (A, B) showed good stability after up to 10 days of irradiation. Films with medium concentrations of titanium oxide (C, D) were stable for many days. Formulations with high titanium oxide content (D, E) were stable for two or more days.

TABLE
Results from UV irradiation of P-NIL formulations
coated on glass.^{a,b}

| | Initial | Time | RI^{c} at | Added Metal |
|---|---|---|---|---|
| Formulation | RI^{c} | (hours) | Time | oxides |
| Formulation A | 1.71 | 264 | 1.74 | SnO₂, ZrO₂ |
| Formulation B | 1.76 | 230 | 1.77 | Al₂O₃, ZrO₂ |
| Formulation C | 1.79 | 244 | 1.84 | SnO₂, ZrO₂ |
| Formulation D | 1.83 | 42 | 1.84 | Al₂O₃, SnO₂ |
| Formulation E | 1.85 | 100 | 1.90 | SnO₂, ZrO₂ |
| Formulation F | 1.93 | 42 | 1.94 | SnO₂, ZrO₂ |
| Formulations containing TiO₂ nanoparticles with no | | | | |
| additional metal oxides | | | | |
| Formulation X1 | 1.79 | 41 | 1.56^{d} | NONE |
| Formulation X2 | 1.90 | 18 | 1.76^{d} | NONE |

^{a}The films were 0.8 to 2.0 micron thickness on 180 micron thick glass. Irradiation was with light from a xenon arc source filtered through a Daylight Q filter. Stress conditions were 0.35 W/(m² · nm) at 340 nm and 45° C..
^{b}The base resins had RI of the cured films of 1.53 to 1.55 at 589 nm.
^{c}Refractive Indices (RI) were measured with a prism coupler and/or an ellipsometer.
^{d}The low RI value indicates that the film has been destroyed.

### INDUSTRIAL APPLICABILITY

The present disclosure provides a method for fabricating high-resolution nanometer features using a UV-stabilized photo nanoimprint lithography (P-NIL) resin, which finds industrial applicability across a variety of sectors that demand nanofabrication, including optical device manufacturing, augmented reality, virtual reality, mixed reality, semiconductor fabrication, and biotechnology. The disclosed method enables the creation of high-resolution nanoscale features with superior optical and mechanical properties by employing a UV-stabilized P-NIL resin that includes a polymerizable organic component, titanium oxide nanoparticles modified with one or more additional metal oxides selected from the group consisting of SiO₂, Al₂O₃, ZrO₂, SnO₂, and NiO, and a photoinitiator.

The method includes applying the resin onto a substrate, pressing a mold containing nanometer-sized features into the resin, curing the resin using ultraviolet light, and removing the mold to produce a cured structure with high-resolution nanometer features. The curing process uses UV-A light from an LED source and may or may not occur under nitrogen or an inert atmosphere to reduce oxygen inhibition.

The disclosed method is useful in optical device manufacturing, where it can be employed to fabricate photonic devices such as optical waveguides, diffusers, and lenses. These devices require precise nanoscale features to control light transmission and refraction. The titanium oxide nanoparticles, modified with the metal oxides listed above, mitigate photocatalytic degradation and enhance the longevity and optical performance of the fabricated structures. In the field of augmented reality, virtual reality, and mixed reality technologies, the high refractive index and UV stability of the P-NIL resin make it ideal for creating lightweight, compact optical components that enhance field of view and optical clarity.

The use of transparent molds ensures uniform UV exposure, enabling accurate reproduction of nanometer-sized features with minimal defects. The curing of the resin under nitrogen or inert atmospheres prevents oxygen inhibition, ensuring robust polymerization and mechanically stable end-products. Furthermore, the use of UV-A LED light sources reduces energy consumption and increases efficiency by enabling faster curing times with precise control over the photopolymerization process. The disclosed method's versatility and adaptability to various substrates, coupled with its compatibility with advanced manufacturing techniques, demonstrate its significant industrial applicability and enable technological advancements across diverse fields.

What is claimed is:

1. A UV-stabilized photo nanoimprint lithography (P-NIL) resin comprising:
an organic binder selected from the group consisting of: acrylate monomeric components, acrylate oligomeric polymerizable components, and acrylated polymers;
titanium oxide (TiO₂) inorganic nanoparticles dispersed in the P-NIL resin, the titanium oxide inorganic nanoparticles having one or more metal oxides coated on or added into the titanium oxide particles, the metal oxides are selected from the group consisting of: SiO₂, Al₂O₃, ZrO₂, SnO₂, and NiO; and
a light-activated initiator for polymerization of acrylates.

2. The UV-stabilized photo nanoimprint lithography (P-NIL) resin of claim 1, further including a radical scavenger selected from the group consisting of the HALS type, ascorbate type, and hydroquinone type.

3. The UV-stabilized photo nanoimprint lithography (P-NIL) resin of claim 1, further including an adhesion promoter for acrylates.

4. The resin of claim 1, further comprising a radical scavenger selected from the group consisting of: hindered amine light stabilizers (HALS), ascorbate compounds, and hydroquinone derivatives.

5. The resin of claim 1, wherein the titanium oxide nanoparticles are coated with SiO₂ and ZrO₂.

6. The resin of claim 1, wherein the nanoparticles have an average size of less than 50 nm.

7. The resin of claim 1, wherein the polymerizable organic component has a refractive index greater than 1.4 at 589 nm.

8. The resin of claim 1, wherein the cured resin exhibits a refractive index greater than 1.7 at 589 nm.

9. The resin of claim 1, further comprising an adhesion promoter selected from silane-based adhesion promoters.

10. The resin of claim 1, wherein the photoinitiator is selected to activate under UV-A light between 320 and 400 nm.

11. A photo nanoimprint lithography (P-NIL) resin comprising:
a polymerizable organic component;
nanoparticles having titanium oxide or titanium oxide modified with one or more additional metal oxides selected from the group consisting of SiO₂, Al₂O₃, ZrO₂, SnO₂, and NiO; and
a photoinitiator for curing the polymerizable organic component.

12. The resin of claim 11, wherein the nanoparticles are capped with an organic coating to prevent agglomeration.

13. The resin of claim 11, wherein the titanium oxide nanoparticles are modified with a combination of two or more additional metal oxides.

14. The resin of claim 11, further comprising an additive to adjust the viscosity of the resin for improved imprinting performance.

15. The resin of claim 11, wherein the polymerizable organic component comprises a mixture of acrylate monomers and oligomers.

16. The resin of claim 11, wherein the photoinitiator is sensitive to UV-A and visible light.

17. The resin of claim 11, wherein the cured resin is suitable for optical waveguides or augmented reality devices.

18. A method for fabricating high-resolution nanometer features using a UV-stabilized photo nanoimprint lithography (P-NIL) resin, comprising:
providing a P-NIL resin having: a polymerizable organic component, a titanium oxide nanoparticle modified with one or more additional metal oxides selected from the group consisting of SiO₂, Al₂O₃, ZrO₂, SnO₂, and NiO, and a photoinitiator;
applying the resin onto a substrate;
pressing a mold containing nanometer-sized features into the resin;
curing the resin using ultraviolet (UV) light; and
removing the mold to produce a cured resin with nanometer features.

19. The method of claim 18, further comprising:
including additional components in the P-NIL resin, the components selected from the group consisting of radical scavengers, adhesion promoters, and polymerizable organic compounds having a refractive index greater than 1.4 at 589 nm, wherein the cured resin exhibits a refractive index greater than 1.7 at 589 nm.

20. The method of claim 19, further comprising:
sizing the nanoparticles to an average diameter of less than 50 nm to minimize light scattering and enhance optical clarity.
